(19) United States
(12) Patent Application Publication
(10) Pub. No.: US 2026/0353907 A1
(43) Pub. Date: Nov. 5, 2026

(54) CONDUCTIVE TRANSPARENT SUBSTRATES FOR SOLAR CELLS

(71) Applicants: NIPPON SHEET GLASS COMPANY, LIMITED, Tokyo (JP); PILKINGTON GROUP LIMITED, Nr. Ormskirk Lancashire (GB)

(72) Inventors: Naoya KOBAMOTO, Tokyo (JP); Satoshi TANAKA, Tokyo (JP); Jun NI, Maumee, OH (US); Lila Raj DAHAL, Perrysburg, OH (US); Srikanth VARANASI, Ottawa Hills, OH (US); Keiko TSURI, Tokyo (JP)

(21) Appl. No.: 19/194,110

(22) Filed: Apr. 30, 2025

(51) Int. Cl. H10K 30/40; H10F 10/17; H10K 30/86

(52) U.S. Cl. CPC H10K 30/40; H10K 30/86; H10F 10/17

(57) ABSTRACT

An electrically conductive transparent substrate for a solar cell includes: a light-transmitting substrate; a light-transmitting electrically conductive layer facing a face of the substrate; and a buffer layer made of a material with a resistance higher than a resistance of a material of the electrically conductive layer and facing a face of the electrically conductive layer which face is opposite to the substrate.

### TECHNICAL FIELD

The present invention relates to an electrically conductive transparent substrate for use in a solar cell and including a light-transmitting element.

### BACKGROUND ART

A solar cell includes a sequential stack of, for example, a light-transmitting substrate such as a glass substrate, a light-transmitting electrically conductive layer, an electron transport layer, a light absorption layer, a hole transport layer, and an electrode. The light absorption layer receives light and generates pairs of electrons and positive hole serving as carriers, the movement of which allows the solar cell to generate electricity.

The solar cell may let electrons and positive holes be dispersed in layers such as the light absorption layer and the electrode to recombine with one another. This reduces carriers and thereby decreases the efficiency of electricity generation by the solar cell.

### CITATION LIST

### Patent Literature

Patent Literature 1

JP 2022-191380 A

### SUMMARY OF INVENTION

### Technical Problem

The present invention has an object of providing an electrically conductive transparent substrate that prevents recombination of carriers and ensures high efficiency of electricity generation.

### Solution to Problem

In order to attain the above object, an electrically conductive transparent substrate for a solar cell as an embodiment of the present invention includes: a light-transmitting substrate; a light-transmitting electrically conductive layer facing a face of the light-transmitting substrate; and a buffer layer made of a material with a resistance higher than a resistance of a material of the electrically conductive layer and facing a face of the electrically conductive layer which face is opposite to the light-transmitting substrate.

The electrically conductive transparent substrate configured as above as a substrate for a solar cell includes a buffer layer, an electrically conductive layer, and a light absorption layer facing a face of the buffer layer which face is opposite to the electrically conductive layer. The buffer layer, which is between the light absorption layer and the electrically conductive layer, restricts the movement of carriers to the light absorption layer.

The solar cell may include a layer such as an electron transport layer (or hole transport layer) between the light absorption layer and the electrically conductive layer to restrict the movement of positive holes (or electrons) to the light absorption layer.

Restricting the movement of carriers to the light absorption layer prevents recombination of carriers, but also restricts the movement of carriers from the light absorption layer, decreasing the efficiency of electricity generation. Preventing the recombination prevents energy from being lost as a result of electric energy being converted into thermal energy; however, the higher resistance leads to increased generation of Joule heat and increased energy loss, adversely affecting the efficiency of electricity generation.

The buffer layer or the combination of the buffer layer and the electron transport layer (or hole transport layer), for example, should be designed appropriately to prevent recombination of carriers and ensure high efficiency in electricity generation (that is, prevent the generation of Joule heat) in a balanced manner.

With the above configuration, adjusting the resistance (that is, band gap) and thickness of the buffer layer easily adjusts the degree of the restriction of the carrier movement to prevent recombination of carriers and ensures high efficiency in electricity generation in a balanced manner. This applies similarly to the case of the solar cell including a layer such as an electron transport layer (or hole transport layer): Adjusting the resistance and thickness of the buffer layer in view of the degree of the restriction of the carrier movement for a layer such as an electron transport layer (or hole transport layer) easily adjusts the degree of the restriction of the carrier movement for the buffer layer. This allows the solar cell to prevent recombination of carriers and ensure high efficiency in electricity generation in a balanced manner.

The electrically conductive transparent substrate may be further configured such that the buffer layer includes silica.

The use of silica (SiO₂), which has a large resistance (that is, band gap), allows a thin buffer layer to ensure high efficiency in electricity generation and restrict the movement of carriers. This allows the solar cell to prevent recombination of carriers and ensure high efficiency in electricity generation in a balanced manner.

The electrically conductive transparent substrate may be further configured such that the buffer layer includes a p-type semiconductor.

The use of a p-type semiconductor for the buffer layer, which has a valence band with large energy at its upper end, allows positive holes to be combined with electrons in the buffer layer and prevents positive holes from moving past the buffer layer. The use of a p-type semiconductor thus allows a thin buffer layer, and the efficiency of electricity generation can be efficiently maintained. With the above configuration, adjusting the resistance and thickness of the buffer layer adjusts the degree of the restriction of the carrier movement for the buffer layer. This allows the solar cell to prevent recombination of carriers and ensure high efficiency in electricity generation in a balanced manner.

The electrically conductive transparent substrate may be further configured such that the buffer layer includes nickel oxide.

The use of nickel oxide (NiOx), which has a large resistance (that is, band gap), allows a thin buffer layer to ensure high efficiency in electricity generation and restrict the movement of positive holes (that is, carriers). This allows the solar cell to prevent recombination of carriers and ensure high efficiency in electricity generation in a balanced manner. The use of nickel oxide, which is included in a solar cell for a hole transport layer, allows efficient formation of the buffer layer.

The electrically conductive transparent substrate may be further configured such that the buffer layer includes: a first buffer sublayer; and a second buffer sublayer facing a face of the first buffer sublayer which face is opposite to the electrically conductive layer, and the first buffer sublayer has a band gap larger than a band gap of the second buffer sublayer.

With the above configuration, adjusting the resistance and thickness of each buffer sublayer more easily adjusts the degree of the restriction of the carrier movement for the buffer layer. This allows the solar cell to easily prevent recombination of carriers and ensure high efficiency in electricity generation in a balanced manner.

In particular, the first buffer sublayer, which is closer to the electrically conductive layer, has a resistance (that is, band gap) larger than that of the second buffer sublayer. This allows the buffer layer to restrict the movement of carriers further in an area closer to the electrically conductive layer for efficient restriction of the movement. This allows the solar cell to prevent recombination of carriers and ensure high efficiency in electricity generation in a balanced manner.

The electrically conductive transparent substrate may be further configured such that the buffer layer has a thickness of not less than 0.5 nm and not more than 2.0 nm in a case where the buffer layer has a band gap of not less than 8.0 eV.

The above configuration allows the solar cell to prevent recombination of carriers and ensure high efficiency in electricity generation in a more balanced manner.

The electrically conductive transparent substrate may be further configured such that the buffer layer has a thickness of not less than 10 nm and not more than 40 nm in a case where the buffer layer has a band gap of not less than 2 eV and not more than 8.0 eV.

The above configuration allows the solar cell to prevent recombination of carriers and ensure high efficiency in electricity generation in a more balanced manner.

The electrically conductive transparent substrate may be further configured such that the buffer layer has a thickness of not less than 0.8 nm and not more than 4.0 nm in a case where the buffer layer includes silica and has a band gap of not less than 9.1 eV.

The above configuration allows the solar cell to prevent recombination of carriers and ensure high efficiency in electricity generation in a more balanced manner.

The electrically conductive transparent substrate may be further configured such that the buffer layer has a thickness of not less than 1.0 nm and not more than 40 nm in a case where the buffer layer includes tin oxide and has a band gap of not less than 3.6 eV.

The above configuration allows the solar cell to prevent recombination of carriers and ensure high efficiency in electricity generation in a more balanced manner.

The electrically conductive transparent substrate may be further configured such that the solar cell is a perovskite solar cell.

The above configuration allows the electrically conductive transparent substrate to prevent recombination of carriers and ensure high efficiency in electricity generation in a balanced manner, and also allows easy use of a perovskite solar cell.

The electrically conductive transparent substrate may be further configured such that the solar cell is an amorphous silicon solar cell.

The above configuration allows the electrically conductive transparent substrate to prevent recombination of carriers and ensure high efficiency in electricity generation in a balanced manner, and also allows easy use of an amorphous silicon solar cell.

### BRIEF DESCRIPTION OF DRAWINGS

FIG. 1 is a diagram schematically illustrating an example configuration of a solar cell.

FIG. 2 is a diagram illustrating how carriers recombine.

FIG. 3 is a diagram illustrating how to prevent recombination of carriers.

FIG. 4 is a diagram illustrating an example configuration of an electrically conductive transparent substrate including a buffer layer with a two-layer structure.

FIG. 5 is a diagram illustrating an example configuration of an electrically conductive transparent substrate including a hole transport layer.

FIG. 6 is a diagram illustrating an example configuration of an electrically conductive transparent substrate including silica for protecting a hole transport layer.

FIG. 7 is a diagram illustrating the configuration of an electrically conductive transparent substrate of, for example, Example 1.

FIG. 8 is a diagram illustrating the configuration of an electrically conductive transparent substrate of, for example, Example 5.

FIG. 9 is a diagram illustrating the configuration of an electrically conductive transparent substrate of, for example, Example 9.

FIG. 10 shows tables of results of evaluation of electrically conductive transparent substrates.

FIG. 11 shows tables of results of evaluation of solar cells.

### DESCRIPTION OF EMBODIMENTS

### Solar Cell

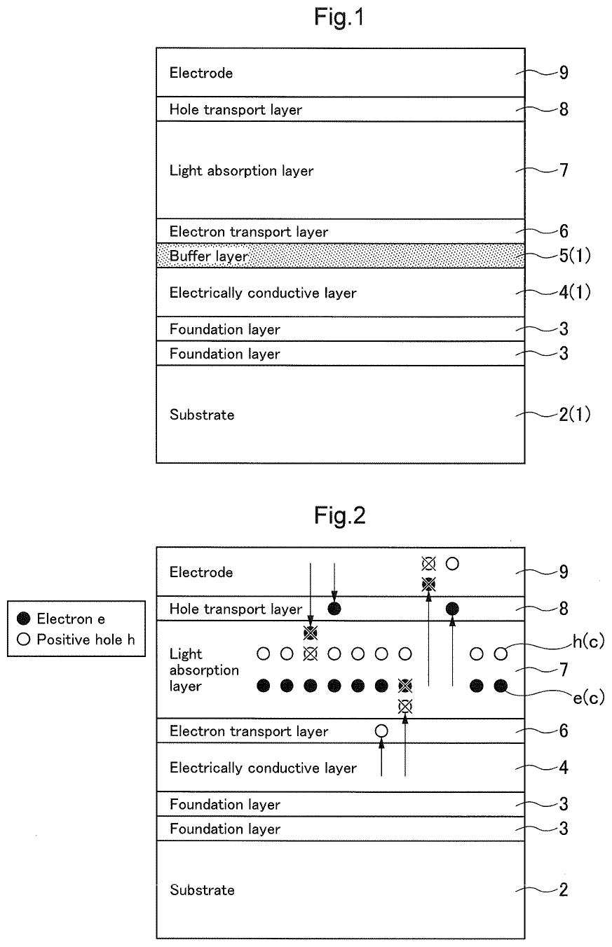

The description below first deals with the configuration of a solar cell for the present embodiment and that of an electrically conductive transparent substrate 1 for use in a solar cell, with reference to FIG. 1. The electrically conductive transparent substrate 1 transmits light, as it is positioned to receive light in a solar cell. The description below assumes the solar cell to be a perovskite solar cell as an example. FIGS. 1 to 9 referred to below each conceptually illustrate a solar cell (or an electrically conductive transparent substrate 1 therein) as seen laterally.

A solar cell generates electricity due to its photovoltaic effect (or photoelectric effect), that is, in response to receiving light to generate carriers c (see FIG. 2) and the carriers c moving. The carriers c include pairs of electrons e and positive holes h (see FIG. 2).

The solar cell for the present embodiment includes a sequential stack of a substrate 2, foundation layers 3, an electrically conductive layer 4, a buffer layer 5, an electron transport layer 6, a light absorption layer 7, a hole transport layer 8, and an electrode 9.

The substrate 2 is made of glass or the like and transmits light. The foundation layers 3 are on a face of the substrate 2 which face is opposite to its light-receiving face, and allow the electrically conductive layer 4 to be joined closely to the substrate 2. The solar cell may include a single foundation layer 3 or two or more foundation layers 3. The drawings each illustrate a solar cell including two foundation layers 3 as an example.

The light absorption layer 7 receives light incident on the substrate 2 and generates pairs of electrons e and positive holes h as carriers c. If the solar cell is a perovskite solar cell, the light absorption layer 7 is made of perovskite.

The electron transport layer 6 efficiently collects electrons e generated in the light absorption layer 7 and transports the electrons e to the electrically conductive layer 4. The electron transport layer 6 includes tin oxide (SnO2), for example.

The electrically conductive layer 4 faces a face of the substrate 2, and transmits light to let the light reach the light absorption layer 7. The electrically conductive layer 4 collects electrons e from the electron transport layer 6 and supplies electric current to an external circuit, meaning that the electrically conductive layer 4 functions as an electrode (specifically, a positive electrode). The electrically conductive layer 4 includes tin oxide (SnO₂), for example, and has a thickness of 200 nm.

The buffer layer 5 is on a face of the electrically conductive layer 4 which face is opposite to the substrate 2. The buffer layer 5 adjusts movement of the carriers c as described later. The buffer layer 5 is made of an insulator such as silicon oxide (SiO₂) with a resistance higher than that of the electrically conductive layer 4.

The hole transport layer 8 efficiently collects positive holes h generated in the light absorption layer 7 and transports the positive holes h to the electrode 9. The hole transport layer 8 includes nickel oxide (NiOx), for example.

The electrode 9 collects positive holes h from the hole transport layer 8 and supplies electric current to an external circuit, meaning that the electrode 9 functions as a positive electrode.

The electrically conductive transparent substrate 1 includes at least a substrate 2, an electrically conductive layer 4, and a buffer layer 5, and may optionally further include layers such as a foundation layer 3 and an electron transport layer 6.

### Recombination

The description below deals with how carriers c recombine in a conventional solar cell, with reference to FIGS. 1 and 2.

As described above, the light absorption layer 7 receives light and generates pairs of electrons e and positive holes h. The positive holes h move to the electrode 9, whereas the electrons e move to the electrically conductive layer 4. These movements allow the solar cell to generate electricity.

The carriers c may be dispersed such that electrons e move from the electrode 9 to the light absorption layer 7 to recombine with positive holes h generated in the light absorption layer 7 or that positive holes h move from the electrically conductive layer 4 to the light absorption layer 7 to recombine with electrons e generated in the light absorption layer 7. Further, electrons e may move to the electrode 9 to recombine with positive holes h from the light absorption layer 7, whereas positive holes h may move to the electrically conductive layer 4 to recombine with electrons e from the light absorption layer 7. Such recombination converts electric energy into thermal energy, resulting in an energy loss and a decrease in the efficiency of electricity generation by the solar cell.

While the electron transport layer 6 and the hole transport layer 8 restrict the movement of carriers c to reduce recombination thereof, restricting the movement more than necessity will prevent positive holes h from moving from the light absorption layer 7 to the electrode 9 or electrons e from moving from the light absorption layer 7 to the electrically conductive layer 4, with the result of a decrease in the efficiency of electricity generation. In other words, restricting the movement of carriers c will lead to higher resistance, so that the movement generates Joule heat, resulting in an electric energy loss and a decrease in the efficiency of electricity generation. The electron transport layer 6 and the hole transport layer 8 are not necessarily capable of easily keeping the efficiency of electricity generation while sufficiently restricting those movements of carriers c which can cause recombination thereof, namely, the movement of electrons e from the electrode 9 to the light absorption layer 7, that of positive holes h from the electrically conductive layer 4 to the light absorption layer 7, that of electrons e to the electrode 9, and that of positive holes h to the electrically conductive layer 4. In other words, the solar cell needs to restrict the movement of carriers c in a balanced manner to keep the efficiency of electricity generation while preventing the recombination.

### Buffer Layer

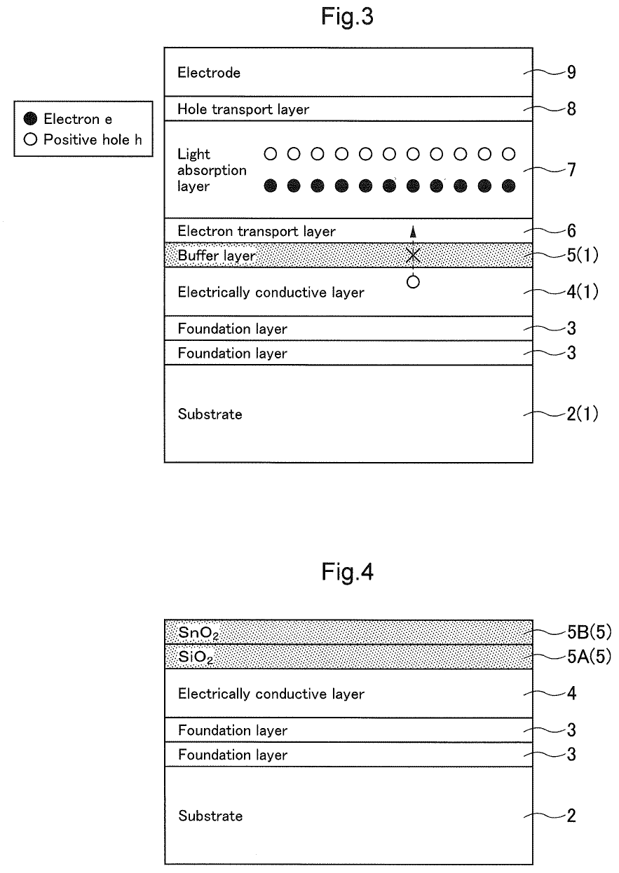

The buffer layer 5 allows the solar cell to easily restrict the movement of carriers c, which can cause recombination thereof, in a balanced manner as mentioned above. The description below deals with how the buffer layer 5 prevents recombination of carriers c, with reference to FIGS. 1 and 3.

The buffer layer 5, which is between the electrically conductive layer 4 and the electron transport layer 6, has a resistance (that is, band gap) larger than that of the electron transport layer 6 and a thickness smaller than that of the electron transport layer 6. In other words, the soler cell includes a buffer layer 5 disposed between the electrically conductive layer 4 and the electron transport layer 6 and having a large resistance and a small thickness.

As described above, positive holes h moving from the electrically conductive layer 4 to the light absorption layer 7 recombine with electrons e generated in the light absorption layer 7. Positive holes h moving from the light absorption layer 7 to the electrically conductive layer 4 recombine in the electrically conductive layer 4 with electrons e generated in the light absorption layer 7 and flowing to the electrically conductive layer 4.

An electron transport layer 6 with a sufficiently large resistance (that is, band gap) restricts the movement of positive holes h from the electrically conductive layer 4 to the light absorption layer 7 and that of positive holes h from the light absorption layer 7 to the electrically conductive layer 4 to prevent the recombination. An electron transport layer 6 with an insufficient resistance does not prevent the recombination.

The present embodiment is configured such that even if the electron transport layer 6 has an insufficient resistance, the buffer layer 5 restricts the movement of positive holes h from the electrically conductive layer 4 to the light absorption layer 7 and that of positive holes h from the light absorption layer 7 to the electrically conductive layer 4. This prevents recombination of electrons e and positive holes h in layers such as the light absorption layer 7 and the electrically conductive layer 4, and allows the solar cell to keep its efficiency of electricity generation.

A buffer layer 5 with an excessively large resistance (that is, band gap) or an excessively small thickness will restrict the movement of electrons e from the light absorption layer 7 to the electrically conductive layer 4, which movement is necessary for the solar cell to generate electricity. The buffer layer 5 has a resistance and a thickness that are adjusted within a range of an appropriate balance by, for instance, increasing the resistance and decreasing the thickness. This allows the buffer layer 5 to restrict that movement of positive holes h which can cause recombination and keep sufficient the movement of electrons e from the light absorption layer 7 to the electrically conductive layer 4, which movement is necessary to generate electricity. This in turn allows the solar cell to prevent recombination of carriers c and ensure high efficiency in electricity generation in a balanced manner.

Specifically, it has been found that if the buffer layer 5 has a resistance (that is, band gap) of not less than 8.0 eV, the buffer layer 5 should have a thickness of not less than 0.5 nm and not more than 2.0 nm, preferably not less than 0.8 nm and not more than 1.6 nm. This allows the solar cell to prevent recombination of carriers c and ensure high efficiency in electricity generation in a balanced manner.

It has been found that if the buffer layer 5 has a resistance of not less than 2 eV and not more than 8.0 eV, the buffer layer 5 should have a thickness of not less than 10 nm and not more than 40 nm, preferably not less than 10 nm and not more than 30 nm. This allows the solar cell to prevent recombination of carriers c and ensure high efficiency in electricity generation in a balanced manner.

It has been found that if the buffer layer 5 includes silica (SiO₂) and has a resistance of not less than 9.1 eV, the buffer layer 5 should have a thickness of preferably not less than 0.8 nm and not more than 4.0 nm. This allows the solar cell to prevent recombination of carriers c and ensure high efficiency in electricity generation in a balanced manner.

It has been found that if the buffer layer 5 includes tin oxide (SnO₂) and has a resistance of not less than 3.6 eV, the buffer layer 5 should have a thickness of preferably not less than 1.0 nm and not more than 40 nm. This allows the solar cell to prevent recombination of carriers c and ensure high efficiency in electricity generation in a balanced manner.

### Buffer Layer Made of Two Sublayers

The buffer layer 5 may have a single-layer structure or a two-layer structure including a first buffer sublayer 5A and a second buffer sublayer 5B as illustrated in FIG. 4.

The first buffer sublayer 5A is on a face of the electrically conductive layer 4 which face is opposite to the substrate 2, whereas the second buffer sublayer 5B is on a face of the first buffer sublayer 5A which face is opposite to the electrically conductive layer 4. The two-layer structure facilitates adjusting the resistance (that is, band gap) and thickness of the buffer layer 5. This allows the solar cell to easily prevent recombination of carriers c and ensure high efficiency in electricity generation in a balanced manner.

The first buffer sublayer 5A should preferably have a band gap larger than that of the second buffer sublayer 5B. In other words, the first buffer sublayer 5A, which is closer to the electrically conductive layer 4, should preferably have a band gap larger than that of the second buffer sublayer 5B. This allows the buffer layer 5 to restrict the movement of positive holes h further at a position closer to the electrically conductive layer 4, thereby efficiently preventing positive holes h from moving from the electrically conductive layer 4 to the light absorption layer 7.

The buffer layer 5, the first buffer sublayer 5A, and the second buffer sublayer 5B should each preferably include at least one of silica (SiO₂), tin oxide (SnO₂), alumina (Al₂O₃), magnesium oxide (MgO), calcium fluoride (CaF), titanium oxide (TiO₂), strontium titanate (SrTiO₃), or a p-type semiconductor as described later. This facilitates adjusting the resistance (that is, band gap) and thickness of the buffer layer 5. The p-type semiconductor is nickel oxide (NiOx), for example. The p-type semiconductor facilitates reducing the thickness of the buffer layer 5 and simultaneously keeping the efficiency of electricity generation.

### Polarity of Electrode

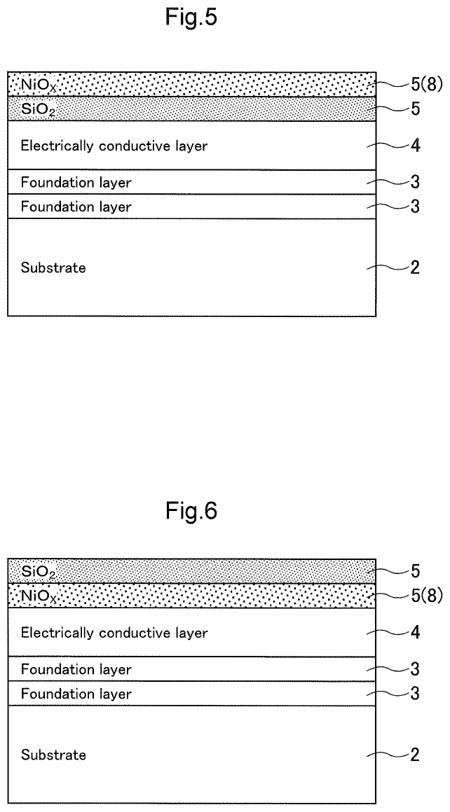

The electrode 9 may be a positive or negative electrode, meaning that the hole transport layer 8 and the electron transport layer 6 in FIG. 1 may be switched around. In this case, the electrically conductive transparent substrate 1, as illustrated in FIG. 5, includes an electrically conductive layer 4, a buffer layer 5 on the electrically conductive layer 4, and a hole transport layer 8 on the buffer layer 5. The buffer layer 5 is made of silica (SiO₂), for example. The hole transport layer 8 is made of nickel oxide (NiOx), for example.

With the above configuration, the buffer layer 5 restricts the movement of electrons e from the electrically conductive layer 4 to the light absorption layer 7 and that of electrons e from the light absorption layer 7 to the electrically conductive layer 4. This prevents recombination of electrons e and positive holes h in layers such as the light absorption layer 7 and the electrically conductive layer 4, and allows the solar cell to keep its efficiency of electricity generation.

Since silica (SiO₂) has a resistance (that is, band gap) larger than that of nickel oxide (NiOx), the above configuration restricts the movement of carriers c efficiently.

Nickel oxide (NiOx) is unstable and easily affected by, for example, a halogen from the light absorption layer 7 of the perovskite solar cell. The solar cell should preferably include a protective oxide film between the nickel oxide (NiOx) and the light absorption layer 7 to prevent a halogen from entering the nickel oxide (NiOx). In this case, the solar cell may, as illustrated in FIG. 6, include a hole transport layer 8 made of nickel oxide (NiOx) on the electrically conductive layer 4 and a buffer layer 5 made of silica (SiO₂) on the hole transport layer 8.

### Examples

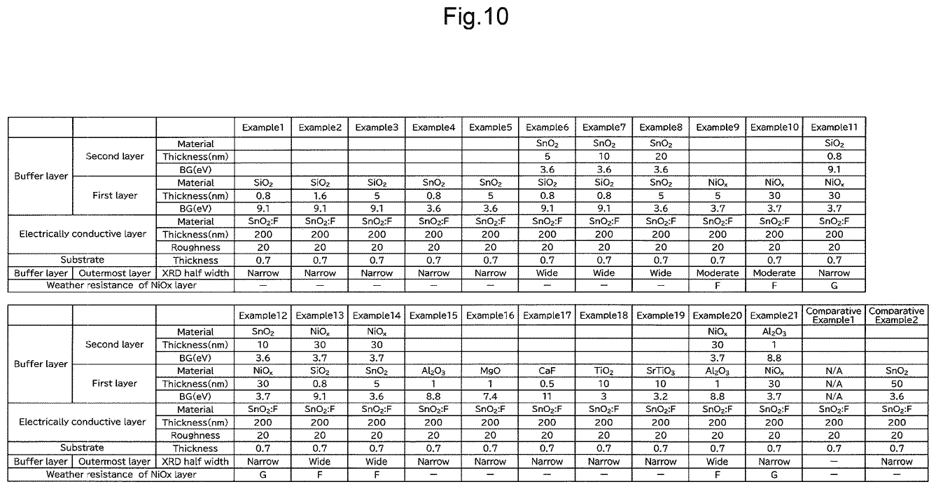

The description below deals with results of evaluation of different electrically conductive transparent substrates 1 and solar cells. Examples 1 to 21 and Comparative Examples 1 and 2 involved respective electrically conductive transparent substrates 1, which each did or did not include a buffer layer 5 and which were configured differently from one another. Examples 101 to 121 and Comparative Examples 101 and 102 involved respective solar cells including respective light absorption layers 7 corresponding to the respective electrically conductive transparent substrates 1 of Examples 1 to 21 and Comparative Examples 1 and 2. In each of Examples 1 to 21 and Comparative Examples 1 and 2, the substrate 2 was a soda lime glass plate with a thickness of 0.7 μm, and the electrically conductive layer 4 was made of fluorine-doped tin oxide (SnO₂) with a roughness of 20. The description below first deals with how the buffer layer 5 was configured in each of Examples 1 to 21 and Comparative Examples 1 and 2, with reference to FIGS. 1 and 10.

### Example 1

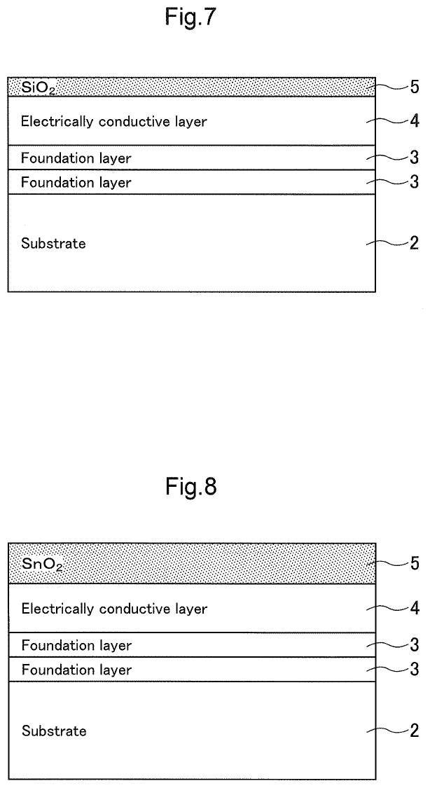

Example 1 involved an electrically conductive transparent substrate 1 including a buffer layer 5 made of silica (SiO₂) as illustrated in FIG. 7 and having a relatively large band gap (BG) of 9.1 eV and a relatively small thickness of 0.8 nm.

### Example 2

Example 2 involved an electrically conductive transparent substrate 1 including a buffer layer 5 made of silica (SiO₂) as illustrated in FIG. 7 and having a relatively large band gap (BG) of 9.1 eV and a relatively small thickness of 1.6 nm.

### Example 3

Example 3 involved an electrically conductive transparent substrate 1 including a buffer layer 5 made of silica (SiO₂) and having a relatively large band gap (BG) of 9.1 eV and a thickness of 5.0 nm.

### Example 4

Example 4 involved an electrically conductive transparent substrate 1 including a buffer layer 5 made of tin oxide (SnO₂) and having a relatively small band gap (BG) of 3.6 eV and a relatively small thickness of 0.8 nm.

### Example 5

Example 5 involved an electrically conductive transparent substrate 1 including a buffer layer 5 made of tin oxide (SnO₂) as illustrated in FIG. 8 and having a relatively small band gap (BG) of 3.6 eV and a relatively large thickness of 5.0 nm.

### Example 6

Example 6 involved an electrically conductive transparent substrate 1 including a buffer layer 5 with a two-layer structure (see FIG. 4), namely, a first buffer sublayer 5A made of silica (SiO₂) and having a relatively large band gap (BG) of 9.1 eV and a relatively small thickness of 0.8 nm and a second buffer sublayer 5B made of tin oxide (SnO 2) and having a relatively small band gap (BG) of 3.6 eV and a relatively large thickness of 5.0 nm.

### Example 7

Example 7 involved an electrically conductive transparent substrate 1 including a buffer layer 5 with a two-layer structure (see FIG. 4), namely, a first buffer sublayer 5A made of silica (SiO₂) and having a relatively large band gap (BG) of 9.1 eV and a relatively small thickness of 0.8 nm and a second buffer sublayer 5B made of tin oxide (SnO₂) and having a relatively small band gap (BG) of 3.6 eV and a relatively large thickness of 10 nm.

### Example 8

Example 8 involved an electrically conductive transparent substrate 1 including a buffer layer 5 with a two-layer structure (see FIG. 4), namely, a first buffer sublayer 5A made of tin oxide (SnO₂) and having a relatively small band gap (BG) of 3.6 eV and a relatively large thickness of 5.0 nm and a second buffer sublayer 5B made of tin oxide (SnO₂) and having a relatively small band gap (BG) of 3.6 eV and a relatively large thickness of 20 nm. Example 8 is identical in configuration to the electrically conductive transparent substrate 1 in FIG. 4 except that the first buffer sublayer 5A was made of not silica (SiO₂) but tin oxide (SnO₂).

### Example 9

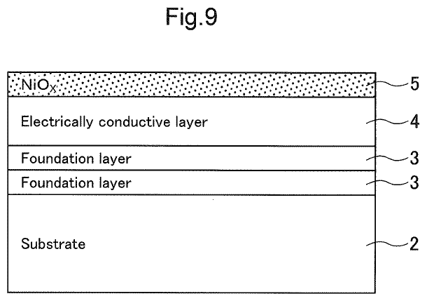

Example 9 involved an electrically conductive transparent substrate 1 including a buffer layer 5 made of a p-type semiconductor as illustrated in FIG. 9. Specifically, the buffer layer 5 was made of nickel oxide (NiOx) and had a relatively small band gap (BG) of 3.7 eV and a relatively large thickness of 5.0 nm. The buffer layer 5 may function as a hole transport layer 8.

### Example 10

Example 10 involved an electrically conductive transparent substrate 1 including a buffer layer 5 made of a p-type semiconductor as illustrated in FIG. 9. Specifically, the buffer layer 5 was made of nickel oxide (NiOx) and had a relatively small band gap (BG) of 3.7 eV and a relatively large thickness of 30 nm. The buffer layer 5 may function as a hole transport layer 8.

### Example 11

Example 11 involved an electrically conductive transparent substrate 1 including a buffer layer 5 with a two-layer structure (see FIGS. 4 and 6), namely, a first buffer sublayer 5A made of nickel oxide (NiOx) as illustrated in FIG. 6 and having a relatively small band gap (BG) of 3.7 eV and a relatively large thickness of 30 nm and a second buffer sublayer 5B made of silica (SiO₂) or alumina (Al₂O₃) and having a relatively large band gap (BG) of 9.1 eV and a relatively small thickness of 0.8 nm. It has been found that if the first buffer sublayer 5A is made of nickel oxide (NiO₂), the second buffer sublayer 5B should preferably be made of alumina (Al₂O₃).

### Example 12

Example 12 involved an electrically conductive transparent substrate 1 including a buffer layer 5 with a two-layer structure (see FIG. 4), namely, a first buffer sublayer 5A made of nickel oxide (NiOx) and having a relatively small band gap (BG) of 3.7 eV and a relatively large thickness of 30 nm and a second buffer sublayer 5B made of tin oxide (SnO 2) and having a relatively small band gap (BG) of 3.6 eV and a relatively large thickness of 10 nm.

### Example 13

Example 13 involved an electrically conductive transparent substrate 1 including a buffer layer 5 with a two-layer structure (see FIGS. 4 and 5), namely, a first buffer sublayer 5A made of silica (SiO₂) as illustrated in FIG. 5 and having a relatively large band gap (BG) of 9.1 eV and a relatively small thickness of 0.8 nm and a second buffer sublayer 5B made of nickel oxide (NiOx) and having a relatively small band gap (BG) of 3.7 eV and a relatively large thickness of 30 nm.

### Example 14

Example 14 involved an electrically conductive transparent substrate 1 including a buffer layer 5 with a two-layer structure (see FIG. 4), namely, a first buffer sublayer 5A made of tin oxide (SnO₂) and having a relatively small band gap (BG) of 3.6 eV and a relatively large thickness of 5.0 nm and a second buffer sublayer 5B made of nickel oxide (NiOx) and having a relatively small band gap (BG) of 3.7 eV and a relatively large thickness of 30 nm. Example 14 is identical in configuration to the electrically conductive transparent substrate 1 in FIG. 4 except that the first buffer sublayer 5A was made of not silica (SiO₂) but tin oxide (SnO₂) and that the second buffer sublayer 5B was made of not silica (SiO₂) but nickel oxide (NiOx).

### Example 15

Example 15 involved an electrically conductive transparent substrate 1 including a buffer layer 5 made of alumina (Al₂O₃) and having a relatively large band gap (BG) of 8.8 eV and a relatively small thickness of 1.0 nm.

### Example 16

Example 16 involved an electrically conductive transparent substrate 1 including a buffer layer 5 made of magnesium oxide (MgO) and having a relatively large band gap (BG) of 7.4 eV and a relatively small thickness of 1.0 nm.

### Example 17

Example 17 involved an electrically conductive transparent substrate 1 including a buffer layer 5 made of calcium fluoride (CaF) and having a relatively large band gap (BG) of 11 eV and a relatively small thickness of 0.5 nm.

### Example 18

Example 18 involved an electrically conductive transparent substrate 1 including a buffer layer 5 made of titanium oxide (TiO₂) and having a relatively small band gap (BG) of 3.0 eV and a relatively large thickness of 10 nm.

### Example 19

Example 19 involved an electrically conductive transparent substrate 1 including a buffer layer 5 made of strontium titanate (SrTiO₃) and having a relatively small band gap (BG) of 3.2 eV and a relatively large thickness of 10 nm.

### Example 20

Example 20 involved an electrically conductive transparent substrate 1 including a buffer layer 5 with a two-layer structure (see FIG. 4), namely, a first buffer sublayer 5A made of alumina (Al₂O₃) and having a relatively large band gap (BG) of 8.8 eV and a relatively small thickness of 1.0 nm and a second buffer sublayer 5B made of nickel oxide (NiOx) and having a relatively small band gap (BG) of 3.7 eV and a relatively large thickness of 30 nm.

### Example 21

Example 21 involved an electrically conductive transparent substrate 1 including a buffer layer 5 with a two-layer structure (see FIG. 4), namely, a first buffer sublayer 5A made of nickel oxide (NiOx) and having a relatively small band gap (BG) of 3.7 eV and a relatively large thickness of 30 nm and a second buffer sublayer 5B made of alumina (Al₂O₃) and having a relatively large band gap (BG) of 8.8 eV and a relatively small thickness of 1.0 nm.

### Comparative Example 1

Comparative Example 1 involved an electrically conductive transparent substrate without a buffer layer.

### Comparative Example 2

Comparative Example 2 involved an electrically conductive transparent substrate 1 including a buffer layer 5 made of tin oxide (SnO2) and having a relatively small band gap (BG) of 3.6 eV and a relatively large thickness of 50 nm.

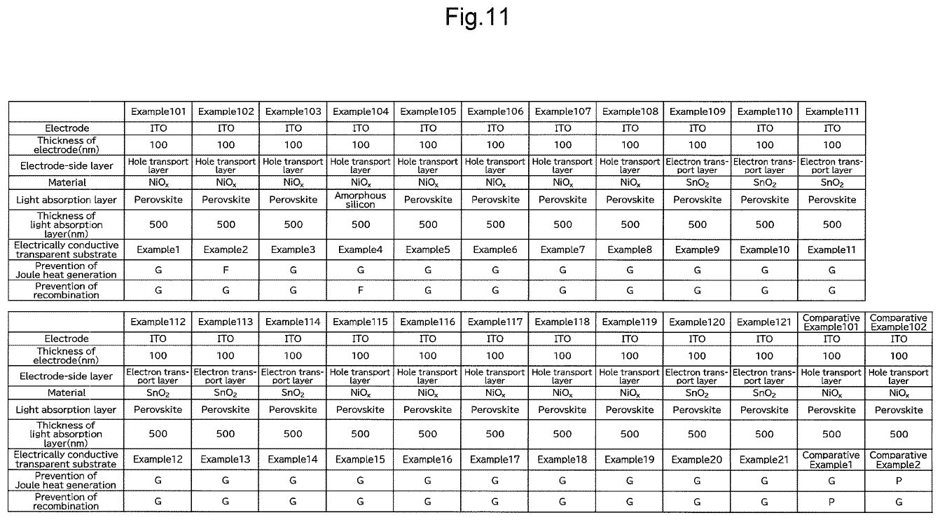

The description below deals with the respective configurations of solar cells of Examples 101 to 121 and Comparative Examples 101 and 102 with reference to FIGS. 1 and 11. The solar cells included the respective electrically conductive transparent substrates 1 of Examples 1 to 21 and Comparative Examples 1 and 2 together with respective light absorption layers 7. The solar cells each included an electrode 9 in the form of a transparent conductive film made of indium tin oxide(ITO) and with a thickness of 100 nm.

### Example 101

Example 101 involved a solar cell including the electrically conductive transparent substrate 1 of Example 1, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 102

Example 102 involved a solar cell including the electrically conductive transparent substrate 1 of Example 2, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 103

Example 103 involved a solar cell including the electrically conductive transparent substrate 1 of Example 3, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 104

Example 104 involved a solar cell including the electrically conductive transparent substrate 1 of Example 4, a light absorption layer 7 made of amorphous silicon and having a thickness of 500 nm, and a hole transport layer 8 made of nickel oxide (NiOx) as an electrode-side layer between the light absorption layer 7 and an electrode 9 serving as a positive electrode.

### Example 105

Example 105 involved a solar cell including the electrically conductive transparent substrate 1 of Example 5, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 106

Example 106 involved a solar cell including the electrically conductive transparent substrate 1 of Example 6, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 107

Example 107 involved a solar cell including the electrically conductive transparent substrate 1 of Example 7, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 108

Example 108 involved a solar cell including the electrically conductive transparent substrate 1 of Example 8, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 109

Example 109 involved a solar cell including the electrically conductive transparent substrate 1 of Example 9, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 110

Example 110 involved a solar cell including the electrically conductive transparent substrate 1 of Example 10, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 111

Example 111 involved a solar cell including the electrically conductive transparent substrate 1 of Example 11, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 112

Example 112 involved a solar cell including the electrically conductive transparent substrate 1 of Example 12, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 113

Example 113 involved a solar cell including the electrically conductive transparent substrate 1 of Example 13, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 114

Example 114 involved a solar cell including the electrically conductive transparent substrate 1 of Example 14, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 115

Example 115 involved a solar cell including the electrically conductive transparent substrate 1 of Example 15, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 116

Example 116 involved a solar cell including the electrically conductive transparent substrate 1 of Example 16, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 117

Example 117 involved a solar cell including the electrically conductive transparent substrate 1 of Example 17, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 118

Example 118 involved a solar cell including the electrically conductive transparent substrate 1 of Example 18, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 119

Example 119 involved a solar cell including the electrically conductive transparent substrate 1 of Example 19, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Example 120

Example 120 involved a solar cell including the electrically conductive transparent substrate 1 of Example 20, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Example 121

Example 121 involved a solar cell including the electrically conductive transparent substrate 1 of Example 21, a light absorption layer 7 made of perovskite (HC(NH₂)₂PBI₃) and having a thickness of 500 nm, and an electron transport layer 6 made of tin oxide (SnO₂) as an electrode-side layer between the light absorption layer 7 and an electrode 9 serving as a negative electrode.

### Comparative Example 101

Comparative Example 101 involved a solar cell including the electrically conductive transparent substrate 1 of Comparative Example 1, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Comparative Example 102

Comparative Example 102 involved a solar cell including the electrically conductive transparent substrate 1 of Comparative Example 2, a light absorption layer 7 made of perovskite (HC(NH₂)₂PBI₃) and having a thickness of 500 nm, and a hole transport layer 8 made of nickel oxide (NiOx) as an electrode-side layer between the light absorption layer 7 and an electrode 9 serving as a positive electrode.

### Evaluation

The description below deals with the results of evaluation of the electrically conductive transparent substrates 1 and the solar cells of the above Examples and Comparative Examples with reference to FIGS. 1, 2, 10, and 11. FIG. 10 shows the respective configurations of the electrically conductive transparent substrates 1 and the results of evaluation thereof. The tables of FIG. 10 show the results of evaluating in a predetermined manner the weather resistance of nickel oxide (NiOx) for the cases in each of which the buffer layer 5 included nickel oxide. The tables show “Wide”, “Narrow”, or “Moderate” to indicate the result of determining the X-ray diffraction half width in a predetermined manner. FIG. 11 shows the respective configurations of the solar cells and the results of evaluation thereof. The tables of FIG. 11 similarly show the results of evaluation of the efficiency of electricity generation (that is, the effect of preventing generation of Joule heat) and the effect of preventing recombination of carriers c. The tables show “G” to mean “good”, “P” to mean “poor”, or “F” to mean “fair” or not good but not completely inappropriate.

FIGS. 10 and 11 indicate the following: A buffer layer 5 with a resistance (that is, band gap) of 8.0 eV and a thickness of not less than 0.5 nm and not more than 2.0 nm generally prevents recombination of carriers c and ensures high efficiency in electricity generation.

A buffer layer 5 with a resistance of not less than 2 eV and not more than 8.0 eV and a thickness of not less than 10 nm and not more than 40 nm prevents recombination of carriers c and ensures high efficiency in electricity generation.

A buffer layer 5 including silica (SiO₂) with a resistance of not less than 9.1 eV and a thickness of not less than 0.8 nm and not more than 4.0 nm sufficiently prevents recombination of carriers c and ensures high efficiency in electricity generation.

A buffer layer 5 including tin oxide (SnO₂) with a resistance of 3.6 eV and a thickness of not less than 1.0 nm and not more than 40 nm prevents recombination of carriers c and ensures high efficiency in electricity generation.

A buffer layer 5 with a two-layer structure easily prevents recombination of carriers c and ensures high efficiency in electricity generation.

A buffer layer 5 prevents recombination of carriers c and ensures high efficiency in electricity generation as long as the buffer layer 5 has adjusted resistance and/or thickness even if it includes a material other than a p-type semiconductor for silica (SiO₂), tin oxide (SnO₂), or nickel oxide (NiOx).

A buffer layer 5 prevents recombination of carriers c and ensures high efficiency in electricity generation as long as the buffer layer 5 has adjusted resistance and thickness regardless of whether the solar cell includes a hole transport layer 8 or an electron transport layer 6 toward the electrode 9.

A buffer layer 5 prevents recombination of carriers c and ensures high efficiency in electricity generation as long as the buffer layer 5 has adjusted resistance and thickness regardless of whether the solar cell is a perovskite solar cell or an amorphous silicon solar cell.

### Alternative Embodiments

(1) The embodiment described above is configured such that the buffer layer 5 has a resistance (that is, band gap) larger than that of the electron transport layer 6 and a thickness smaller than that of the electron transport layer 6. The present invention is, however, not limited to such a configuration. The buffer layer 5 may have any resistance or thickness. Adjusting the resistance and thickness of the buffer layer 5 in accordance with the configuration of the solar cell easily prevents recombination of carriers c and ensures high efficiency in electricity generation.

(2) The solar cell for any of the embodiments described above is not necessarily a perovskite solar cell and may, as indicated by the evaluation results above, be any of various solar cells such as an amorphous silicon solar cell including a light absorption layer 7 made of amorphous silicon and a solar cell including a light absorption layer 7 made of a semiconductor such as silicon.

(3) The buffer layer 5 for any of the embodiments described above does not necessarily include two sublayers, but may be divided into three or more sublayers. This facilitates adjusting the resistance (that is, band gap) and thickness of the buffer layer 5. It is preferable to design the sublayers of the buffer layer 5 such that the buffer layer 5 has a resistance that is larger toward the electrically conductive layer 4. This efficiently prevents positive holes h from moving from the electrically conductive layer 4 to the light absorption layer 7.

The buffer layer 5 may include two or more sublayers with respective resistances that vary in stages. The buffer layer 5 may, as a whole, have a resistance with a gradient. The buffer layer 5 may, in other words, have a resistance that is gradually larger toward the electrically conductive layer 4. This efficiently prevents positive holes h from moving from the electrically conductive layer 4 to the light absorption layer 7.

(4) The buffer layer 5 for any of the embodiments described above may be between the hole transport layer 8 and the electrode 9. This prevents recombination of carriers c and simultaneously keeps the movement of positive holes h to the electrode 9 to keep the efficiency of electricity generation.

### Industrial Applicability

The present invention is applicable to a solar cell and an electrically conductive transparent substrate for use in a solar cell.

### Reference Signs List

1 Electrically conductive transparent substrate
2 Substrate
3 Foundation layer
4 Electrically conductive layer
5 Buffer layer
5A First buffer sublayer
5B Second buffer sublayer
6 Electron transport layer
7 Light absorption layer
8 Hole transport layer
9 Electrode
C Carrier
e Electron
h Positive hole

1. (canceled)

2. (canceled)

3. The electrically conductive transparent substrate according to claim 6, wherein
the buffer layer includes a p-type semiconductor.

4. The electrically conductive transparent substrate according to claim 6, wherein
the buffer layer includes nickel oxide.

5. The electrically conductive transparent substrate according to claim 6, wherein
the buffer layer includes:
a first buffer sublayer; and
a second buffer sublayer facing a face of the first buffer sublayer which face is opposite to the electrically conductive layer, and
the first buffer sublayer has a band gap larger than a band gap of the second buffer sublayer.

6. An electrically conductive transparent substrate for a solar cell,
the electrically conductive transparent substrate comprising:
a light-transmitting substrate;
a light-transmitting electrically conductive layer facing a face of the light-transmitting substrate; and
a buffer layer made of a material with a resistance higher than a resistance of a material of the electrically conductive layer and facing a face of the electrically conductive layer wherein the face of the electrically conductive layer is opposite to the light-transmitting substrate.
wherein the electrically conductive layer is made of fluorine-doped tin oxide, and
the buffer layer has a thickness of not less than 0.5 nm and not more than 2.0 nm in a case where the buffer layer has a band gap of not less than 8.0 eV.

7. The electrically conductive transparent substrate according to claim 6, wherein
the buffer layer has a thickness of not less than 10 nm and not more than 40 nm in a case where the buffer layer has a band gap of not less than 2 eV and not more than 8.0 eV.

8. An electrically conductive transparent substrate for a solar cell,
the electrically conductive transparent substrate comprising:
a light-transmitting substrate;
a light-transmitting electrically conductive layer facing a face of the light-transmitting substrate; and
a buffer layer made of a material with a resistance higher than a resistance of a material of the electrically conductive layer and facing a face of the electrically conductive layer wherein the face of the electrically conductive layer is opposite to the light-transmitting substrate,
wherein the electrically conductive layer is made of fluorine-doped tin oxide, and
the buffer layer has a thickness of not less than 0.8 nm and not more than 4.0 nm in a case where the buffer layer includes silica and has a band gap of not less than 9.1 eV.

9. The electrically conductive transparent substrate according to claim 6, wherein
the buffer layer has a thickness of not less than 1.0 nm and not more than 40 nm in a case where the buffer layer includes tin oxide and has a band gap of not less than 3.6 eV.

10. The electrically conductive transparent substrate according to claim 6, wherein
the solar cell is a perovskite solar cell.

11. The electrically conductive transparent substrate according to claim 6, wherein
the solar cell is an amorphous silicon solar cell.

12. The electrically conductive transparent substrate according to claim 8, wherein
the buffer layer includes a p-type semiconductor.

13. The electrically conductive transparent substrate according to claim 8, wherein
the buffer layer includes nickel oxide.

14. The electrically conductive transparent substrate according to claim 8, wherein
the buffer layer includes:
a first buffer sublayer; and
a second buffer sublayer facing a face of the first buffer sublayer which face is opposite to the electrically conductive layer, and
the first buffer sublayer has a band gap larger than a band gap of the second buffer sublayer.

15. The electrically conductive transparent substrate according to claim 8, wherein
the buffer layer has a thickness of not less than 10 nm and not more than 40 nm in a case where the buffer layer has a band gap of not less than 2 eV and not more than 8.0 eV.

16. The electrically conductive transparent substrate according to claim 8, wherein
the buffer layer has a thickness of not less than 1.0 nm and not more than 40 nm in a case where the buffer layer includes tin oxide and has a band gap of not less than 3.6 eV.

17. The electrically conductive transparent substrate according to claim 8, wherein
the solar cell is a perovskite solar cell.

18. The electrically conductive transparent substrate according to claim 8, wherein
the solar cell is an amorphous silicon solar cell.
